(19) United States
(12) Patent Application Publication
(10) Pub. No.: US 2003/0106013 A1
(43) Pub. Date: Jun. 5, 2003

(54) Architecture for multi-symbol encoding and decoding

(76) Inventors: Michael D. Jarchi, Northridge, CA (US); Satish K. Sridharan, West Hills, CA (US)

Correspondence Address: INFINERA CORPORATION, 1322 BORDEAUX DRIVE, SUNNYVALE, CA, 94089, US

(21) Appl. No.: 10/301,174

(22) Filed: Nov. 20, 2002

Related U.S. Application Data
(60) Provisional application No. 60/332,040, filed on Nov. 21, 2001.

(51) Int. Cl. H03M 13/00

(52) U.S. Cl. 714/784

(57) ABSTRACT

An error correction system for coding codewords comprises a multi-symbol encoder and a multi-symbol decoder for respectively encoding codewords using a multi-symbol per clock and decoding codewords using a multi-symbol per clock. The multi-symbol encoder and decoder may employ Reed-Solomon codes for encoding and decoding process.

This application claims priority of U.S. provisional application, Serial No. 60/332,040, filed Nov. 21, 2001, which application is incorporated herein by its reference.

### BACKGROUND OF THE INVENTION

1. Field of the Invention

This invention relates generally to forward error correction systems, and in particular to a system using a multi-symbol per clock architecture for encoding and decoding words.

2. Description of the Related Art

Digital electronic systems store and transmit copious amounts of information. Storage or transmission of digital information sometimes results, however, in corruption of some of the data. Defects in a storage media, or errors in the reading and writing of data from a storage media, may result in data errors. Similarly, transmission of data through a transmission channel may result in errors, through noise in the transmission channel or the inability of the transmitting or receiving unit to properly transmit or read data. As data storage and data transmission may be viewed as transmitting data to a media using a transmitting unit, and thereafter reading the data using a receiving unit, the remaining discussion will be in terms generally of data transmission.

Forward error correction (FEC) is often employed to increase transmitted data reliability. Generally speaking, FEC systems encode data using an encoder at a transmitter and decode data using a decoder at the receiver. During encoding redundant information is added to the data. The redundant information allows determination by receiving units as to whether data corruption has occurred, and if so, the data that has been corrupted. Thus, the redundant information allows the data to be corrected within limits. The decoder generally decodes the data, generates an error polynomial, and uses the error polynomial to determine corrections to the data.

The encoded data is generally grouped in terms of codewords. One type of codes falls in a category of block codes where a codeword is comprised of n symbols, of which k symbols are information symbols. The code word therefore contains n−k redundant symbols. The symbols are data words comprised of m bits. In a systematic encoding system, the n−k redundant symbols are appended to the information symbols, while in a non-systematic code the information symbols are also modified. For instance, for BCH codes, n=2^{m}−1 and k=n−mt. To correct t bits within the code word, mt bits of overhead/redundancy is needed. Each of the k and n symbols is made of 1 bit. For Reed-Solomon (RS) codes, n=2^{m}−1 and k=n−2t. For RS codes, to correct t symbols within the code word, 2t symbols of redundancy are needed. Each of the k and n symbols comprise m bits.

As shown in FIG. 1, a codeword consists of 255 symbols, where each symbol is 8 bits. Of these 255 symbols, 239 are the information to be encoded and the remaining 16 are the FEC Check symbols. The encoding process may be configured to place logical “0” in FEC check digit locations, i.e., providing FEC bit stuffing. The G.709 Specification is based upon four G.975 FEC Frames where sixteen RS(255,239) codewords are to be interleaved in order to ease product development by reducing logic processing speeds, as well as benefit for burst error correction. Of the 239 symbols of information in the codeword, G.709 uses one symbol for Optical Channel Overhead (OCh) regarding the transmission channel and other functions. Of the remaining 238, two are reserved for 40G implementation and one is reserved for a 10G application. The encoder rate conversion buffer handles these functions in constructing the requisite 239 symbols of information.

As data transmission rates increase in communication networks, for instance from 2.5 Gbps to 10 Gbps to 40 Gbps, the encoder and decoder have to process the data at increasing faster bit rates. One technique to improve the processing rate in the encoder and the decoder is to increase the core clock frequencies. However, this requires the use of more advanced semiconductor process technologies. Even with the use of these advanced technologies, there could be significant difficulties of being able to achieve such high clock frequencies.

An alternate approach, which is the subject of this invention, is to architect the encoder and decoder such that more data is processed employing a slower core clock frequency. This would enable the encoder and decoder to be implemented without the use of the most advanced semiconductor process technology. This reduces implementation risk and the cost of the devices. For instance, with a RS(255,239) code word, a conventional method of processing the encoder and decoder is to process one symbol per clock and it thus takes 255 clocks to process one codeword. However, if 3 symbols are processed per clock, then it takes only 85 clocks to process the codeword and, hence, the required clock frequency can be a slower clock rate.

There have been other architectures that process all the symbols of the codeword in one clock cycle, but those architectures employ an extensive parallel processing architecture resulting in a tremendous increase in the complexity of the encoder and the decoder. By using an intermediate approach, the core clock frequencies and the complexity of the coding devices can be both optimized.

### SUMMARY OF THE INVENTION

According to this invention, a forward error correction system employs architecture of processing multiple code symbols per clock cycle in order to reduce the core clock frequencies. In an exemplary embodiment, a multi-symbol encoding and decoding architecture for an RS(255,239) code word is utilized.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts:

FIG. 1 is an example of Reed-Solomon RS(255,239) codeword.

FIG. 2 is a schematic overview of a data transmission system.

FIG. 3 is a schematic illustration of a known single-symbol encoding and decoding scheme.

FIG. 4 is a schematic illustration of multi-symbol encoding and decoding scheme in accordance with this invention.

FIG. 5 is a block diagram of the encoder module comprising this invention.

FIG. 6 is multi-symbol process encoding architecture utilized in this invention.

### DETAILED DESCRIPTION OF THE INVENTION

FIG. 2 illustrates a data transmission system 10 which utilizes FEC coding. Information data 11 is provided to an encoder 12. Encoder 12 forms information words from the data and multiplies the information words by a generator matrix to form a codeword. Alternatively, the remainder is computed when the information vector is divided by the generator polynomial as the remainder and is subsequently added to the original information vector to form the codeword. The output 13 of the encoder 13 is then transmitted over a noisy channel 14 where the data may be corrupted due to nonlinearities and other impairments of system 10. The transmitted data 13 is received by the decoder 15 and decoded to correct the errors that occurred during transmission and to retrieve the original information data 11.

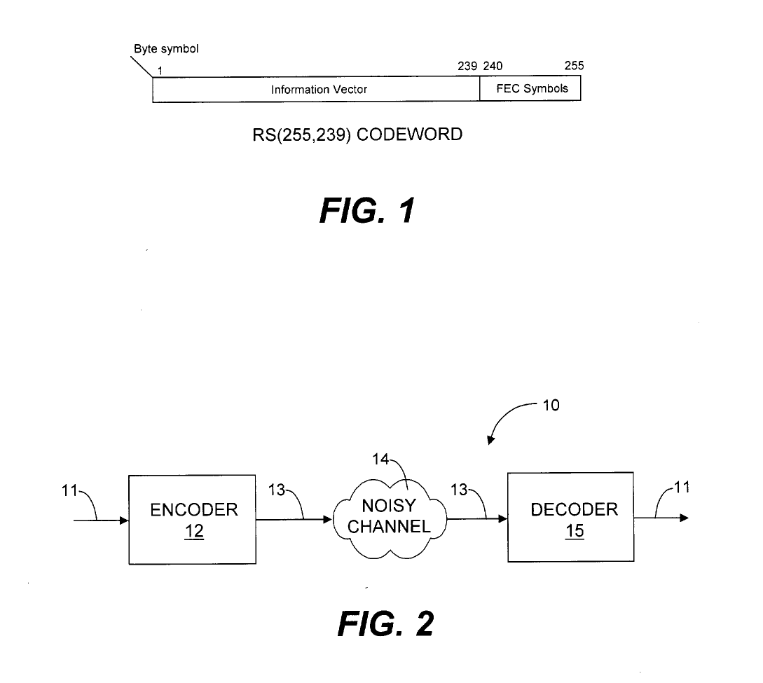

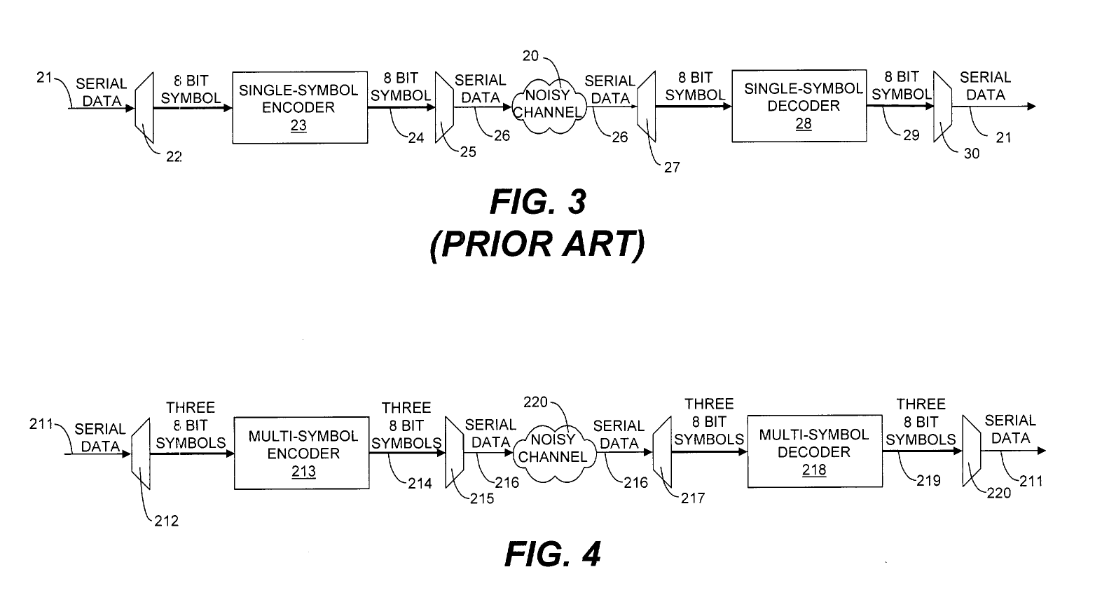

In the conventional coding scheme illustrated in FIG. 3, one symbol is processed per clock during encoding and decoding. As an example, a Reed-Solomon (255,239) code is considered where 8 bits comprise a symbol. The RS codeword is 239×8-bit information bits and 16×8-bit redundant bits as seen in FIG. 1. In FIG. 2, the incoming data stream 21 is demultiplexed at 22 to an 8 bit symbol and then encoded by a single-symbol encoder 23. After encoding, the 8 bit symbol on encoded output 24 is multiplexed at 25 up to a single bit and the serial data 26 is provided for transmission on channel 20. During transmission, errors occur. On the receiver side, the serial data 26 is demultiplexed at 27 to an 8 bit symbol to be processed by a single-symbol decoder 28. After decoding, the resulting 8 bit symbol 29 is multiplexed at 30 to a single bit to retrieve the original information data 21.

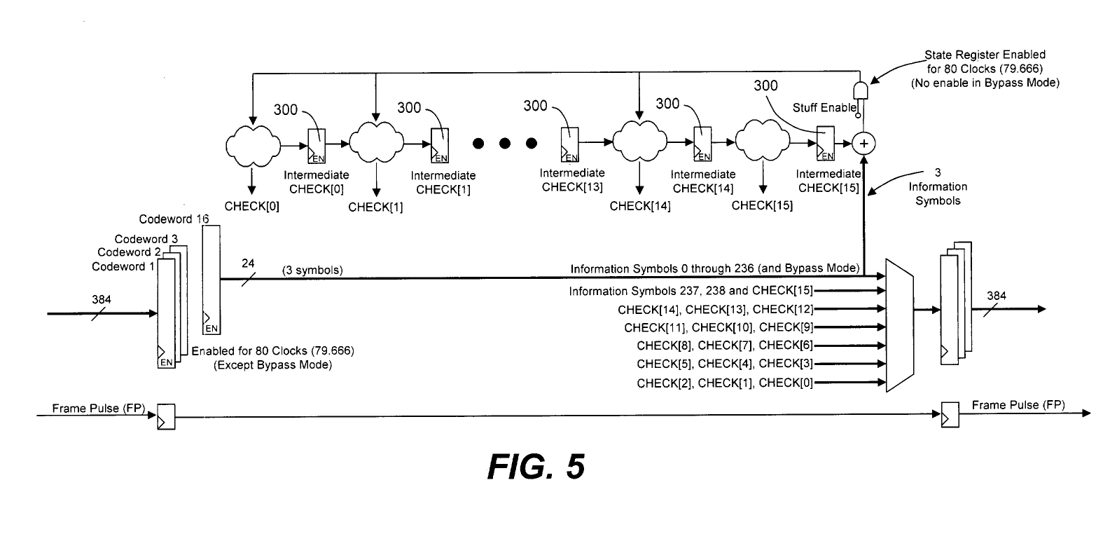

The present invention is illustrated in FIG. 4. In the case here, encoder 213 performs multi-symbol encoding, such as, for example, performing multi-symbol (255,239) Reed-Solomon encoding. As the incoming serial information data stream 211 is received, it is transformed at multiplexer 212 into three 8-bit symbols before the encoding process begins. The multi-symbol encoder 213 then processes three symbols per clock cycle by performing a “look-ahead” operation illustrated in FIG. 5. During each of the clocks, the information symbols are transmitted out. With reference to the RS codeword shown in FIG. 1, after 79 clocks, 237 of the 239 information symbols have been processed and transmitted. During the 80^{th} clock, the remaining 2 information symbols are processed and transmitted with the first of the sixteen redundancy symbols. At the end of the 85^{th} clock all the 239 information symbols and all of the 16 redundancy symbols have been transmitted as data at 214 in FIG. 3. This information data is then multiplexed at 215 and then provided as output 216 for transmission on channel 220. Alternatively, 5 symbols can be processed per clock resulting in a total of 51 clocks to perform encoding of one codeword.

Errors occur during transmission and the data received by the receiver is represented by data 216 where it is transformed into three symbols at demultiplexer 217 before the decoding process begins. In decoder 218, three symbols are processed per clock cycle. The first step of the decoding process is to compute the syndrome. In the conventional process of operating on one received symbol per clock, it takes 255 clocks to compute the syndrome. In this embodiment, three symbols are processed per clock cycle and, therefore, it takes 85 clocks to obtain the syndrome. It is thus possible to obtain the syndrome using a slower clock frequency. Once the syndrome is obtained, the error locator and error magnitude polynomials are calculated. Using the error locator and error magnitude polynomials, the error at each symbol is computed to assemble the error vector. In the conventional approach of FIG. 2, one error symbol is evaluated per clock cycle and it, therefore, takes 255 clocks to assemble the entire vector. In FIG. 3, three error symbols are computed per clock cycle and, therefore, it takes only 85 clocks to assemble the entire error vector. During each clock cycle as the error symbols are computed, they are subtracted from the incoming code word containing errors to obtain the original encoded codeword. The information symbols can then be extracted from the codeword. The output of decoder 218 is a 3 symbol bus 219, which output is then multiplexed at 200 to a single bit to retrieve the information data 211.

With reference to FIG. 5, the encoding architecture of this invention, for example, performs the Reed-Solomon RS(255,239) systematic encoding for 16 codewords in parallel to construct the G.975 FEC Frame per the ITU G.709 Specification. As previously indicated, the RS(255,239) Codeword consists of 255 symbols, where each symbol is 8 bits. Of these 255 symbols, 239 are the information to be encoded and the remaining 16 are the FEC Check symbols. Data is provided to the encoder module in 384-bit words per each clock, along with a frame pulse (FP) to identify the beginning of the G.709 frame. 384 bits represent three 8-bit symbols per each codeword (3 symbols×8-bit/symbol×16 codewords=384 bits). Given the information vector for each RS(255,239) codeword is 239 8-bit symbols, this means that 79.666 clocks contain the data to be encoded. In a traditional RS encoder, the information vector is processed one symbol per clock to generate the FEC check symbols as indicated relative to FIG. 3. In the architecture shown in FIGS. 4-6, the architecture is designed to reduce core operating speed and device power so that the first 79 processing clocks employ three symbols and the 80th processing clock only employs two symbols of the three that are passed through the encoder.

The complete RS(255,239) codeword is 255 symbols (bytes) in length. With the 16 codeword interleave specified by G.709, this yields a total of 4080 symbol bytes per FEC frame. The encoder module outputs three symbols per clock for each codeword (384 bits) which yields 85 clocks per FEC frame. As described above, the first 79.666 clocks contain the information vector to be encoded; the remaining 5.333 clocks are for output of the FEC check symbols (5.333×3 symbols/clock=16). The output encoded frame will provide a frame pulse (FP) with the first data of the first G.975 FEC frame of the G.709 frame.

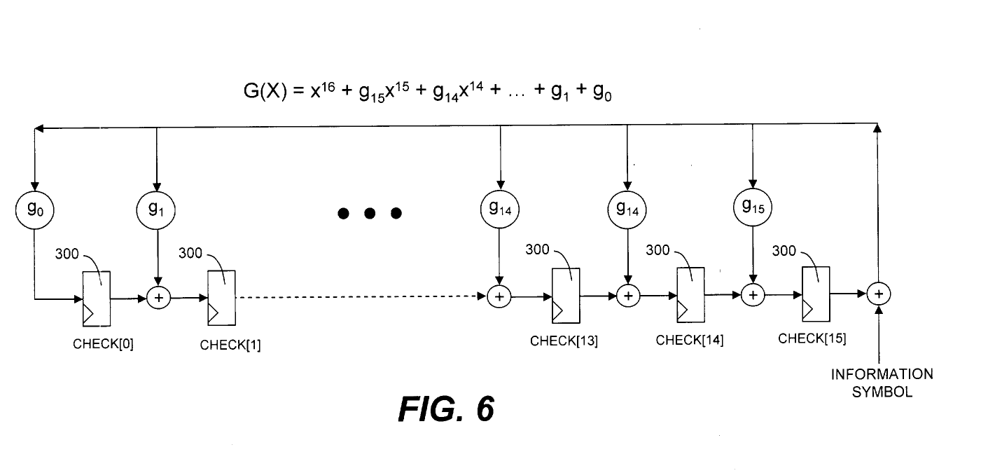

Reference is now made to FIG. 6 together with FIG. 5 which illustrate the multi-symbol process encoding architecture in more detail. RS encoder with respect to the architecture of this invention utilizes the information vector which is divided by the generator polynomial G(x) to obtain the FEC check symbols (CHECK[15:0]). This is performed on a per symbol basis starting with the most significant information symbol being multiplied by the coefficients of G(x), i.e., g₀, g₁, . . . g₁₃, g₁₄ and g₁₅.. Note, however, that this partial calculation is added to the next symbol calculation via the coefficients of G(X) ), i.e., g₀, g₁, . . . g₁₃, g₁₄ and g₁₅, from registers 300 comprising intermediate CHECK[0], intermediate CHECK[1] . . . intermediate CHECK[14] and intermediate CHECK[15], for each of the k information symbols. In the example, three information symbols per processing clock are employed as seen in FIG. 5. To achieve this, the state equations for each of the CHECK registers 300 must be calculated as if three processing clocks have actually occurred. An anomaly to this process for N=3, for N multi-symbol encoding, is that there are 239 information symbols to be encoded which does not result in an integer when divided by 3. Thus, the last processing clock must provide a different state equation path to represent only 2 information symbols that are being processed. Additionally, for this same processing clock which generates the final state of the FEC check digits, the most significant digit must be an output at the next clock. Finally, all the CHECK symbols are multiplexed and transmitted as serial data as shown in FIG. 5. It should be noted that other values N for multi-symbols can be processed per clock, other than N=3. For example, as previously indicated, five symbols can be processed per clock by the decoder resulting in 51 clocks to compute the syndrome and 51 clocks to compute all the error symbols.

As an illustrative example, the state calculations for register CHECK[15] are shown below. The bold letters with grey background below indicating variable changes for each of the sixteen CHECK registers:

(S₀+CHECK[15])g₁₅+CHECK[14] CHECK[15] after symbol S₀

((S₀+CHECK[15])g₁₅+CHECK[14]+S₁)g₁₅+(S₀+CHECK[15])g₁₄+CHECK[13] CHECK[15] after symbol S₁

(((S₀+CHECK[15])g₁₅CHECK[14]+S₁)g₁₅+(S₀+CHECK[15])g₁₄+CHECK[13]+S2)g₁₅+((S₀+CHECK[15])g₁₅+CHECK[14]+S₁)g₁₄+(S₀+CHECK[15])g₁₃+CHECK[12] CHECK[15] after symbol S₂

These equations for CHECK[15] expand and reduce to:

(S₀+CHECK[15])g₁₅²+(S₁+CHECK[14])g₁₅+(S₀+CHECK[15])g₁₄+CHECK[13] 2 symbol

(S₀+CHECK[15])g₁₅³+(S₁+CHECK[14])g₁₅²+(S₂+CHECK[13])g₁₅+(S₁+CHECK[14])g₁₄+(S₀+CHECK[15])g₁₃+CHECK[12] 3 symbol

The equations for the fifteen remaining CHECK register states are calculated similarly. State equations for registers CHECK[0] and CHECK[1] will reduce further due to fewer terms. Thus, this architecture will enable faster aggregate information data rates in realizable ASIC technologies with lower timing closure impacts.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications and variations as may fall within the spirit and scope of the appended claims.

What is claimed is:

1. An error correction system for coding codewords, comprising a multi-symbol encoder and decoder for respectively encoding codewords using a multi-symbol per clock and decoding codewords using a multi-symbol per clock.

2. The error correction system of claim 1 further comprising a multi-symbol encoder and decoder employing Reed-Solomon codes during encoding and decoding.

3. The error correction system of claim 1 where a multi-symbol is employed during encoding and decoding comprising RS(255,239) codewords.

4. The error correction system of claim 1 wherein three symbols are processed per clock during encoding and three symbols are processed per clock during decoding.

5. The error correction system of claim 4 wherein RS(255,239) codewords are during encoding and decoding.
